(19) United States
(12) Patent Application Publication
(10) Pub. No.: US 2009/0003111 A1
(43) Pub. Date: Jan. 1, 2009

(54) Noise accommodating information storing apparatus

(76) Inventors: Ming Zhang, Folsom, CA (US); Greg Taylor, Portland, OR (US); Norbert Seifert, Beaverton, OR (US)

Correspondence Address: LAW OFFICE OF DONALD D. MONDUL;c/o INTELLEVATE, P.O. BOX 52050, MINNEAPOLIS, MN, 55402, US

(21) Appl. No.: 11/824,476

(22) Filed: Jun. 29, 2007

(51) Int. Cl. G11C 7/02

(52) U.S. Cl. 365/214

(57) ABSTRACT

An apparatus including a plurality of semiconductor devices coupled via a plurality of circuit paths to store information. Selected circuit paths of the plurality of circuit paths present increased resistance, the increased resistance being sufficient to cooperate with capacitance present in the apparatus to establish a resistive-capacitive (RC) time constant in the selected circuit paths. The RC time constant being appropriate to accommodate a noise signal having a predetermined duration without the apparatus losing stored information.

### BACKGROUND

With reductions in supply voltages being employed in products today, lit may be more difficult to distinguish stored data from noise. Noise may be generated by semiconductor devices themselves, or may be radiation induced such as noise measured as Soft Error Rate (SER) in an apparatus. There is a need in semiconductor information storage apparatuses for improving reliability of operation in the presence of noise.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates a prior art information storing apparatus;

FIG. 2 illustrates a first embodiment of an information storing apparatus configured according to the teachings of the present description;

FIG. 3 illustrates a second embodiment of an information storing apparatus configured according to the teachings of the present description;

FIG. 4 illustrates a third embodiment of an information storing apparatus configured according to the teachings of the present description; and

FIG. 5 illustrates a fourth embodiment of an information storing apparatus configured according to the teachings of the present description.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

Embodiments of the present invention may include apparatuses for performing the operations herein. An apparatus may be specially constructed for the desired purposes, or it may comprise a general purpose computing device selectively activated or reconfigured by a program stored in the device. Such a program may be stored on a storage medium, such as, but not limited to, any type of disk including floppy disks, optical disks, compact disc read only memories (CD-ROMs), magnetic-optical disks, read-only memories (ROMs), random access memories (RAMs), electrically programmable read-only memories (EPROMs), electrically erasable and programmable read only memories (EEPROMs), magnetic or optical cards, or any other type of media suitable for storing electronic instructions, and capable of being coupled to a system bus for a computing device.

The processes and displays presented herein are not inherently related to any particular computing device or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the invention as described herein. In addition, it should be understood that operations, capabilities, and features described herein may be implemented with any combination of hardware (discrete or integrated circuits) and software.

Use of the terms “coupled” and “connected”, along with their derivatives, may be used. It should be understood that these terms are not intended as synonyms for each other. Rather, in particular embodiments, “connected” may be used to indicate that two or more elements are in direct physical or electrical contact with each other. “Coupled” my be used to indicated that two or more elements are in either direct or indirect (with other intervening elements between them) physical or electrical contact with each other, and/or that the two or more elements co-operate or interact with each other (e.g. as in a cause and effect relationship).

FIG. 1 illustrates a prior art information storing apparatus. In FIG. 1, an information storing apparatus 10 may include a PMOS (P-channel Metal Oxide Semiconductor) transistor device 12 having a source 14, a gate 16 and a drain 18; a PMOS transistor device 20 having a source 24, a gate 26 and a drain 28; an NMOS (N-channel Metal Oxide Semiconductor) transistor device 30 having a source 34, a gate 36 and a drain 38; and an NMOS transistor device 40 having a source 44, a gate 46 and a drain 48. Sources 14, 24 may be coupled with a supply voltage locus 50 for receiving a supply voltage V_{CC}. Sources 34, 44 may be coupled with a low potential locus 52. Low voltage locus 52 may be at a low voltage potential V_{SS}. Low voltage potential V_{SS} may be a ground potential. Gates 16, 36 may be coupled with drains 28, 48. Gates 26, 46 may be coupled with drains 18, 38.

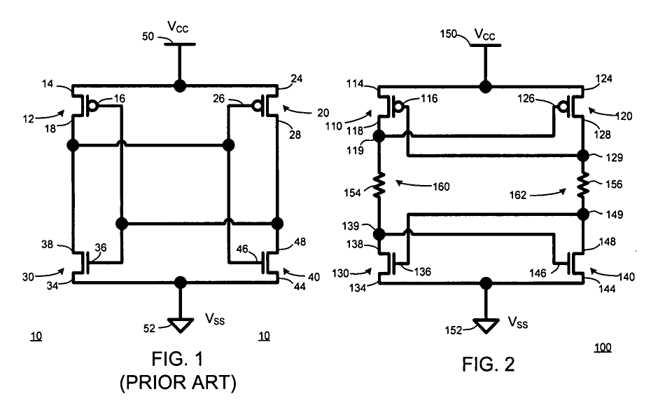

FIG. 2 illustrates a first embodiment of an information storing apparatus configured according to the teachings of the present description. In FIG. 2, an information storing apparatus 100 may include a PMOS transistor device 110 having a source 114, a gate 116 and a drain 118; a PMOS transistor device 120 having a source 124, a gate 126 and a drain 128; an NMOS transistor device 130 having a source 134, a gate 136 and a drain 138; and an NMOS transistor device 140 having a source 144, a gate 146 and a drain 148. Sources 114, 124 may be coupled with a supply voltage locus 150 for receiving a supply voltage V_{CC}. Sources 134, 144 may be coupled with a low potential locus 152. Low voltage locus 152 may be at a low voltage potential V_{SS}. Low voltage potential V_{SS} may be a ground potential. A resistive element 154 may be coupled between drains 118, 138. A resistive element 156 may be coupled between drains 128, 148. Gate 116 may be coupled with a connection locus 129 between drain 128 and resistive element 156. Gate 136 may be coupled with a connection locus 149 between drain 148 and resistive element 156. Gate 126 may be coupled with a connection locus 119 between drain 118 and resistive element 154. Gate 146 may be coupled with a connection locus 139 between drain 138 and resistive element 154.

Resistive element 154 may be embodied in a discrete resistive element in a circuit path 160 coupling drains 118, 138. Resistive element 156 may be embodied in a discrete resistive element in a circuit path 162 coupling drains 128, 148. Alternatively, resistive elements 154, 156 may be embodied in resistive material (i.e., higher resistance than may be employed in coupling other elements of apparatus 100) employed in fashioning circuit paths 160, 162 for at least a portion of each circuit path 160, 162. By way of example and not by way of limitation, such a higher resistive material may be embodied in gate material, or metal interconnect of the sort used for fashioning gates 116, 126, 136, 146. Resistive elements 154, 156 may present sufficient resistance to cooperate with capacitance present in apparatus 100 to establish RC (Resistive-Capacitive) time constants appropriate for permitting apparatus 100 to accommodate a noise signal having a predetermined duration without losing stored data or information in apparatus 100. Noise signals typically may be presented as sharp, short duration spiked signals having a shorter duration than data signals or other signals in an apparatus. Introducing or increasing an RC time constant into operation of an apparatus may cause the apparatus to react more slowly to changes in signals than would be the case with no RC time constant or a lower RC time constant. Such a slower reaction may cause an apparatus to “overlook”, not react to or otherwise accommodate a noise signal without disrupting operation of the apparatus, such as by way of example and not by way of limitation, losing stored information.

One measure of noise may be expressed as SER (Soft Error Rate), a measure known by one skilled in the art of semiconductor design. Resistive elements 154, 156 may be configured to cooperate with capacitance in apparatus 100 to meet or exceed a predetermined SER measure. Capacitance cooperating with resistive elements 154, 156 to establish a desired RC time constant may be found in transistor devices 110, 120, 130, 140, in connections among portions or elements of apparatus 100 (e.g., in circuit paths 160, 162) or elsewhere in apparatus 100.

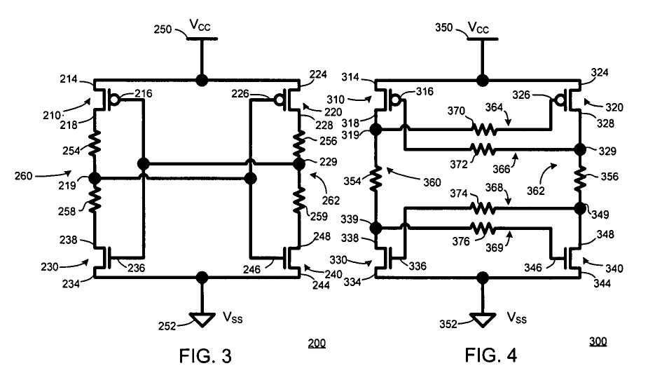

FIG. 3 illustrates a second embodiment of an information storing apparatus configured according to the teachings of the present description. In FIG. 3, an information storing apparatus 200 may include a PMOS transistor device 210 having a source 214, a gate 216 and a drain 218; a PMOS transistor device 220 having a source 224, a gate 226 and a drain 228; an NMOS transistor device 230 having a source 234, a gate 236 and a drain 238; and an NMOS transistor device 240 having a source 244, a gate 246 and a drain 248. Sources 214, 224 may be coupled with a supply voltage locus 250 for receiving a supply voltage V_{CC}. Sources 234, 244 may be coupled with a low potential locus 252. Low voltage locus 252 may be at a low voltage potential V_{SS}. Low voltage potential V_{SS} may be a ground potential. A resistive element 254 may be coupled between drain 218 and a circuit locus 219. A resistive element 258 may be coupled between circuit locus 219 and drain 238. A resistive element 256 may be coupled between drain 228 and a circuit locus 229. A resistive element 259may be coupled between circuit locus 229 and drain 248. Gate 216 may be coupled with gate 236 and circuit locus 229. Gate 226 may be coupled with gate 246 and circuit locus 219.

Resistive elements 254, 256, 258, 259 may be embodied in discrete resistive elements in circuit paths 260, 262. Alternatively, resistive elements 254, 256, 258, 259 may be embodied in resistive material (i.e., higher resistance than may be employed in coupling other elements of apparatus 200) employed in fashioning circuit paths 260, 262 for at least a portion of each circuit path 260, 262. By way of example and not by way of limitation, such a higher resistive material may be embodied in gate material, or metal interconnect of the sort used for fashioning gates 216, 226, 236, 246. Resistive elements 254, 256, 258, 259 may present sufficient resistance to cooperate with capacitance present in apparatus 200 to establish RC (Resistive-Capacitive) time constants appropriate for permitting apparatus 200 to accommodate a noise signal having a predetermined duration without losing stored data or information in apparatus 200.

FIG. 4 illustrates a third embodiment of an information storing apparatus configured according to the teachings of the present description. In FIG. 4, an information storing apparatus 300 may include a PMOS transistor device 310 having a source 314, a gate 316 and a drain 318; a PMOS transistor device 320 having a source 324, a gate 326 and a drain 328; an NMOS transistor device 330 having a source 334, a gate 336 and a drain 338; and an NMOS transistor device 340 having a source 344, a gate 346 and a drain 348. Sources 314, 324 may be coupled with a supply voltage locus 350 for receiving a supply voltage V_{CC}. Sources 334, 344 may be coupled with a low potential locus 352. Low voltage locus 352 may be at a low voltage potential V_{SS}. Low voltage potential V_{SS} may be a ground potential. A resistive element 354 may be coupled between drains 318, 338. A resistive element 356 may be coupled between drains 328, 348. A resistive element 370 may be coupled between gate 326 and a circuit locus 319 located between resistive element 354 and drain 319. A resistive element 372 may be coupled between gate 316 and a circuit locus 329 located between resistive element 356 and drain 328. A resistive element 374 may be coupled between gate 336 and a circuit locus 349 located between resistive element 356 and drain 348. A resistive element 376 may be coupled between gate 346 and a circuit locus 339 located between resistive element 354 and drain 338.

Resistive elements 354, 356, 370, 372, 374, 376 may be embodied in discrete resistive elements in circuit paths 360, 362, 364, 366, 368, 369. Alternatively, resistive elements 354, 356, 370, 372, 374, 376 may be embodied in higher resistance material (i.e., higher resistance than may be employed in coupling other elements of apparatus 300) employed in fashioning circuit paths 360, 362, 364, 366, 368, 369 for at least a portion of each circuit path 360, 362, 364, 366, 368, 369. By way of example and not by way of limitation, such a resistive material may be embodied in gate material, or metal interconnect of the sort used for fashioning gates 316, 326, 336, 346. Resistive elements 354, 356, 370, 372, 374, 376 may present sufficient resistance to cooperate with capacitance present in apparatus 300 to establish RC (Resistive-Capacitive) time constants appropriate for permitting apparatus 300 to accommodate a noise signal having a predetermined duration without losing stored data or information in apparatus 300.

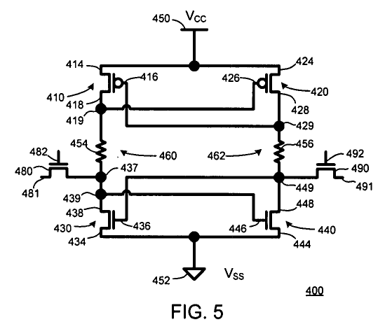

FIG. 5 illustrates a fourth embodiment of an information storing apparatus configured according to the teachings of the present description. In FIG. 5, an information storing apparatus 400 may include a PMOS transistor device 410 having a source 414, a gate 416 and a drain 418; a PMOS transistor device 420 having a source 424, a gate 426 and a drain 428; an NMOS transistor device 430 having a source 434, a gate 436 and a drain 438; and an NMOS transistor device 440 having a source 444, a gate 446 and a drain 448. Sources 414, 424 may be coupled with a supply voltage locus 450 for receiving a supply voltage V_{CC}. Sources 434, 444 may be coupled with a low potential locus 452. Low voltage locus 452 may be at a low voltage potential V_{SS}. Low voltage potential V_{SS} may be a ground potential. A resistive element 454 may be coupled between drains 418, 438. A resistive element 456 may be coupled between drains 428, 448. Gate 416 may be coupled with a connection locus 429 between drain 428 and resistive element 456. Gate 436 may be coupled with a connection locus 449 between drain 448 and resistive element 456. Gate 426 may be coupled with a connection locus 419 between drain 418 and resistive element 454. Gate 446 may be coupled with a connection locus 439 between drain 438 and resistive element 454.

Resistive element 454 may be embodied in a discrete resistive element in a circuit path 460 coupling drains 418, 438. Resistive element 456 may be embodied in a discrete resistive element in a circuit path 462 coupling drains 428, 448. Alternatively, resistive elements 454, 456 may be embodied in higher resistance material (i.e., higher resistance than may be employed in coupling other elements of apparatus 400) employed in fashioning circuit paths 460, 462 for at least a portion of each circuit path 460, 462. By way of example and not by way of limitation, such a higher resistive material may be embodied in gate material of the sort used for fashioning gates 416, 426, 436, 446. Resistive elements 454, 456 may present sufficient resistance to cooperate with capacitance present in apparatus 400 to establish RC (Resistive-Capacitive) time constants appropriate for permitting apparatus 400 to accommodate a noise signal having a predetermined duration without losing stored data or information in apparatus 400.

Apparatus 400 may also include an access device 480 coupled for providing data or information for storing in apparatus 400 from a locus 481 to a circuit locus 437 in response to a gating WRITE command applied at a gate 482. Access device 480 may also read stored information to locus 481 from apparatus 400 in response to a gating READ command applied at gate 482. Apparatus 400 may also include an access device 490 coupled for providing data or information for storing in apparatus 400 from a locus 491 to a circuit locus 449 in response to a gating WRITE command applied at a gate 492. Access device 490 may also read stored information to locus 491 from apparatus 400 in response to a gating READ command applied at gate 492. Access devices 480, 490 may be coupled with apparatus 400 at a lower potential end of resistive elements 454, 456 so that SER or noise contribution by access devices 480, 490 may be minimized. Alternately, access devices 480, 490 may be embodied in PMOS transistor devices and coupled at loci substantially adjacent to 418, 428 (not shown) as may be understood by one skilled in the art of storage unit circuitry design.

Embodiments of the invention may provide noise suppression, improved stability and improved reliability by providing a filtering effect using an RC time constant. Noise generated at a particular drain node may be attenuated when the noise arrives at the neighboring drain node. Embodiments of the invention may also provide noise suppression, improved stability and improved reliability by providing a voltage-division effect by which DC (Direct Current) noise caused, by way of example and not by way of limitation, because of a defective component may have reduced impact at a neighboring node. This voltage-division effect may reduce lower useful limits of supply voltage V_{CC}, by way of example and not by way of limitation, because process variations and defects in resistors have mainly DC impact.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. An apparatus comprising: a plurality of transistor devices coupled via a plurality of circuit paths to store a data bit; and resistive material interposed in selected circuit paths of said plurality of circuit paths between selected loci in the apparatus; said resistive material being configured to provide sufficient resistance in said selected circuit paths to cooperate with capacitance present in the apparatus to establish a resistive-capacitive time constant in said circuit paths sufficient to accommodate a noise signal having a predetermined duration without disrupting operation of the apparatus.

2. An apparatus as recited in claim 1 wherein said plurality of transistor devices are arranged having a first transistor network and a second transistor network coupled generally in parallel; each said transistor network including an NMOS transistor device and a PMOS transistor device with a respective drain-connecting circuit path connecting a drain of said NMOS transistor with a drain of said PMOS transistor; said resistive material being interposed in said respective drain-connecting circuit paths.

3. An apparatus as recited in claim 2 wherein said drain of each NMOS transistor device is coupled with a gate of an NMOS transistor device, and wherein said drain of each PMOS transistor device is coupled with a gate of a PMOS transistor device.

4. An apparatus as recited in claim 1 wherein said resistive material comprises a resistor device coupled in a respective circuit path.

5. An apparatus as recited in claim 2 wherein said resistive material comprises a resistor device coupled in a respective circuit path.

6. An apparatus as recited in claim 1 wherein said resistive material comprises fashioning a respective said circuit path using material exhibiting an increased resistivity.

7. An apparatus as recited in claim 1 wherein said resistive material comprises fashioning a respective said circuit path using gate material.

8. An apparatus as recited in claim 2 wherein said resistive material comprises fashioning a respective said circuit path using gate material.

9. An apparatus as recited in claim 3 wherein said resistive material comprises fashioning a respective said circuit path using gate material.

10. An apparatus comprising: a plurality of semiconductor devices coupled via a plurality of circuit paths to store information; selected circuit paths of said plurality of circuit paths being configured to present increased resistance; said increased resistance being sufficient to cooperate with capacitance present in the apparatus to establish a resistive-capacitive time constant in said selected circuit paths; said resistive-capacitive time constant being appropriate to accommodate a noise signal having a predetermined duration without the apparatus losing stored information.

11. An apparatus as recited in claim 10 wherein said resistive material comprises a resistor device coupled in a respective circuit path.

12. An apparatus as recited in claim 10 wherein said resistive material comprises fashioning a respective said circuit path using material exhibiting an increased resistivity.

13. An apparatus as recited in claim 10 wherein said plurality of semiconductor devices are arranged having a first network and a second network coupled generally in parallel; said selected circuit paths being coupled within each of said first network and said second network.

14. An apparatus as recited in claim 10 wherein said plurality of semiconductor devices are arranged having a first network and a second network coupled generally in parallel; said selected circuit paths being coupled within each of said first network and said second network and being coupled between said first network and said second network.

15. An apparatus as recited in claim 12 wherein said plurality of semiconductor devices are arranged having a first network and a second network coupled generally in parallel; said selected circuit paths being coupled within each of said first network and said second network.
